(19) United States
(12) Patent Application Publication
(10) Pub. No.: US 2025/0008661 A1
(43) Pub. Date: Jan. 2, 2025

(54) DEFLECTION SPRING COMPRESSION MOUNTING

(71) Applicant: Intel Corporation, Santa Clara, CA (US)

(72) Inventors: Arturo Navarro Alvarez, Grecia (CR); Jeff Ku, Taipei (TW); Luis Carlos Sanchez Herrera, Alajuela (CR); Min Suet Lim, Gelugor (MY); Pin Wang, Portland, OR (US); Tongyan Zhai, Portland, OR (US); Raghavendra Ramesh Rao, Bengaluru (IN)

(21) Appl. No.: 18/343,993

(22) Filed: Jun. 29, 2023

(51) Int. Cl. H05K 1/18

(52) U.S. Cl. CPC H05K 1/181; H05K 2201/10159; H05K 2201/10189; H05K 2201/10265; H05K 2201/1031; H05K 2201/10522; H05K 2201/10598; H05K 2201/10606

(57) ABSTRACT

Deflection spring compression mounting is disclosed. A disclosed example deflection spring for an electronics package includes first and second end portions having first and second locking interfaces, respectively, to at least partially constrain the first and second end portions relative to a support, a curved portion, and a medial portion having a third locking interface to fix the medial portion relative to the support, wherein fixing the medial portion relative to the support causes the curved portion to contact and press against the electronics package.

### FIELD OF THE DISCLOSURE

This disclosure relates generally to connectors and, more particularly, to deflection spring compression mounting.

### BACKGROUND

In recent years, compression mounting technology (CMT) connectors have been implemented for random access memory (RAM) devices/modules. Some recent implementations include a Compression Attached Memory Module (CAMM) that is placed onto a printed circuit board (PCB) for communication therewith. Memory modules implementing CAMM technology can offer significant upgrade and/or repair options for an original equipment manufacturer (OEM) or an end user.

For certain memory modules, a connection and/or coupling is defined between connector pins of a memory module and a PCB (e.g., a motherboard, a board module, etc.). Reliability and performance of the connection and/or the electrical coupling between the memory module and the PCB can be dependent on a compression force imparted on individual connector pins. In general, a relatively uniform distribution of pressure across the connector pins can ensure proper electrical and mechanical contact between the memory module and the PCB in terms of resistance, as well as an acceptable level of signal integrity. However, PCB warpage, which may be caused by heat and/or movement, can cause the electrical and mechanical contact associated with the connector pins to degrade and/or diminish over time.

### BRIEF DESCRIPTION OF THE DRAWINGS

FIG. 1 is an exploded view of a known memory device.

FIG. 2 is an isometric view of an example deflection spring constructed in accordance with teachings of this disclosure.

FIG. 3 is an exploded view of the example deflection spring of FIG. 2.

FIG. 4 is an exploded view of another example deflection spring constructed in accordance with teachings of this disclosure.

FIG. 5 is a detailed cross-sectional view of a portion of the example deflection spring of FIG. 4.

FIGS. 6A-6D illustrate example aspects of assembling the example deflection spring shown in FIGS. 4 and 5.

FIGS. 7A-7C illustrate example aspects of disassembling the example deflection spring shown in FIGS. 4-6D.

FIGS. 8A-8C illustrate example stages of disassembling the example deflection spring shown in FIGS. 4-7C.

FIGS. 9A-9D illustrate example stages of disassembling the example deflection spring shown in FIGS. 4-8C.

FIG. 10 is a flowchart representative of an example method to produce and/or assemble examples disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Deflection spring compression mounting and connectors involving the same are disclosed. To ensure a proper connection between a memory module, such as a compression attached memory module (CAMM) and a printed circuit board (PCB) (e.g., a motherboard of a PC, a module, etc.), a connector interface is employed therebetween. In particular, the memory module can have connector pins that are seated into a receptacle of the PCB or vice-versa. However, movement, shock and/or warpage due to heat or temperature cycling can cause the connection to degrade.

Examples disclosed herein enable consistent and highly reliable compression connections by evenly applying an evenly distributed force on at least one component associated with a connector interface. In particular, examples disclosed herein can improve signal integrity and/or reliability by applying a relatively uniform pressure and/or force on components, such as a circuit board or memory modules/packages/chips of a CAMM memory module.

Examples disclosed herein utilize a deflection spring, for instance, an electronics package (e.g., a semiconductor package, a board module, a PCB, a memory board, a memory module, etc.) associated with an electronics device such as a personal computer (PC), a server, a table, a mobile phone, etc. According to examples disclosed herein, first and second end portions (e.g., lateral end portions, distal end portions, etc.) include respective locking interfaces that are utilized to at least partially constrain (e.g., fully constrain, rigidly constrain, etc.) the first and second end portions to at least one support (e.g., a support frame, a backplate, a chassis, etc.). In turn, a medial portion of the deflection spring includes a third locking interface such that pressing on the medial portion to engage the third locking feature with the at least one support causes a curved portion of the deflection spring to contact and press against, for example, a surface of the electronics package. In particular, the medial portion is ramped/raised and/or elevated relative to the lateral end portions such that pushing downward on the medial portion causes an overall deflection of the deflection spring and, in turn, displacement of the curved portion. In some examples, a surface of the electronics package is pushed against a compression connector of another (e.g., second) electronics package or PCB by the aforementioned curved portion.

In some examples, the curved portion extends between the medial portion and at least one of the first and second end portions. In some examples, the third locking interface is engaged with a lever spring of the at least one support. In some such examples, the third locking interface can include a slot-shaped aperture to retain at least a portion of the lever spring (e.g., a distal end portion of the lever spring). In some examples, the first and second locking interfaces respectively include an aperture to receive a fastener that is coupled to a corresponding spacer extending from a support frame (e.g., backplate) of the at least one support. In some examples, the curved portion includes a convex shape (e.g., a convex portion) to contact a surface of the electronics package (e.g., a PCB) in or near the electronics package.

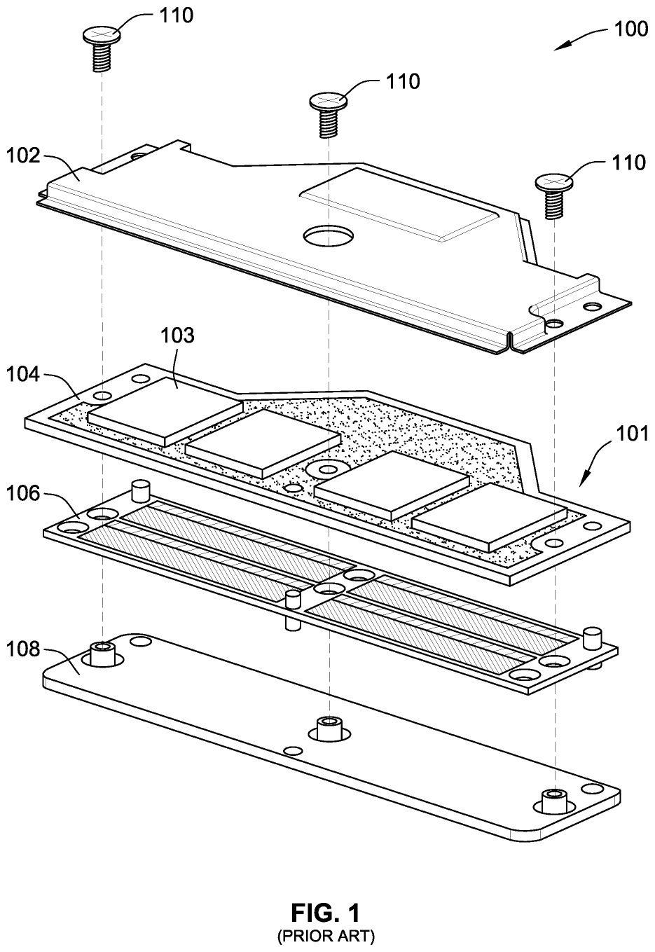

FIG. 1 is an exploded view of a known electronics assembly 100. The electronics assembly 100 is a CAMM technology-based memory module assembly having a shield 102 that covers and/or contacts an electronics package 101 which, in turn, includes memory chips 103 placed on and/or assembled to a PCB 104. The PCB 104 includes contacts (e.g., connector pins, connector pads, etc.) that are pressed onto and/or compressed against a corresponding socket of another PCB (e.g., a motherboard) (not shown). In particular, the PCB 104 is pressed against a compression connector 106 positioned on a support (e.g., a support frame, a chassis, etc.) 108, which is implemented as a backplate (e.g., a board mount backplate). In this known implementation, fasteners 110, which are implemented as screws, are threaded into the backplate 108 to compress the shield 102 against the PCB 104 and, in turn, push the PCB 104 against the compression connector 106, thereby defining electrical contact between the PCB 104 and the compression connector 106.

In this known device, utilizing the fasteners 110 to press the shield 102 against the PCB 104 can result in an uneven compression of the PCB 104 against the compression connector 106. In particular, inconsistent torque of the fasteners 110, part tolerances, fastener variation, hole placement variation and/or component variation can result in uneven compression of the PCB 104 against the compression connector 106. In contrast, examples disclosed herein can enable a relatively evenly distributed force for compression of a connector interface and, thus, improved signal integrity as well as reliability. Further, the known implementation of FIG. 1 can result in a relatively significant height (e.g., a z-stack height).

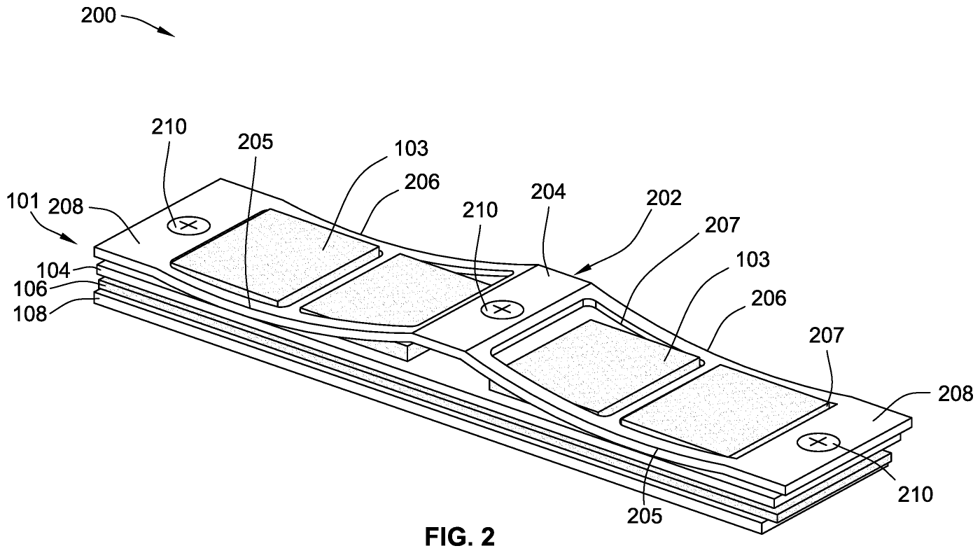

FIG. 2 is an isometric view of an example electronics assembly 200 having an example deflection spring 202 in accordance with teachings of this disclosure. The example deflection spring 202 includes a medial portion (e.g., means for deflecting) 204 having curved portions (e.g., means for contacting an electronics package) 205, intermediate portions 206 with corresponding apertures 207, and end portions (e.g., distal portions, lateral end portions, etc.) 208. In the illustrated view of FIG. 2, the example electronics assembly 200 is implemented as a memory module assembly 200, and also includes the electronics package 101 with the PCB 104 supporting the memory chips 103, the compression connector 106 and the backplate 108 described above in connection with FIG. 1. In this example, the aforementioned apertures 207 are implemented as openings for the memory chips 103 mounted to the PCB 104 of the electronics package 101. Further, example fasteners (e.g., means for locking) 210, which are implemented as flush-mounted shoulder screws exhibiting a taper at their respective heads, are implemented to assemble, position and retain the deflection spring 202, the PCB 104, the compression connector 106 and the backplate 108 together. The example deflection spring 202 can be at least partially composed of a metal (e.g., a sheet metal, steel, aluminum, stainless, steel, nickel, nickel steel, titanium, copper, etc.) or a plastic and/or elastomer. However, any other appropriate material can be implemented instead.

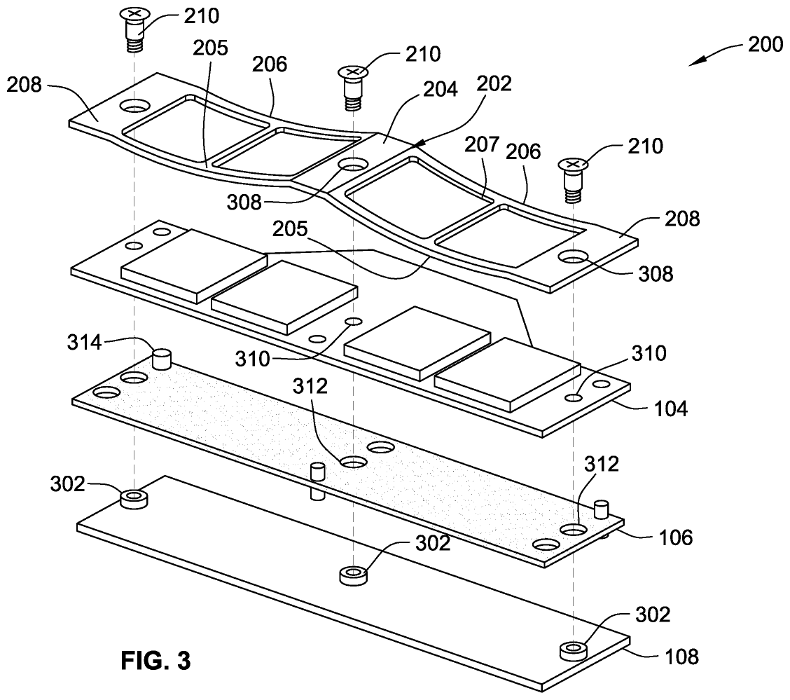

As will be described in greater detail below in connection with FIG. 3, at least partially constraining the deflection spring 202 at the end portions 208 to the backplate 108 via the two fasteners 210 while engaging the fastener 210 to the backplate 108 at the medial portion 204 causes the medial portion 204 to be deflected toward the PCB 104 and, in turn, presses and/or pushes the curved portion 205 against the PCB 104, thereby causing the PCB 104 to engage the compression connector 106 with a relatively even distribution of force across a span and/or surface area thereof.

FIG. 3 is an exploded view of the example memory module assembly 200 depicting the deflection spring 202, the PCB 104, the compression connector 106, the backplate 108 and the fasteners 210. According to examples disclosed herein, the fasteners 210 are attached to (e.g., threaded into) supports (e.g., locks, locking supports, fastener receptacles, etc.) 302, which are implemented as standoffs in this example and mounted to the backplate 108. In particular, the fasteners 210 pass through locking interfaces (e.g., locking features, retention features, means for restraining, means for restraining end portions, etc.) 308, which are implemented as apertures in this example, of the deflection spring 202. The example fasteners 210 additionally pass through apertures 310 of the PCB 104, and apertures 312 of the compression connector 106. However, any other appropriate other fastener, fastener device (e.g., a chemical fastener, a snap interface, etc.) and/or fastening methodology can be implemented instead. In some examples, pins 314 are implemented to facilitate alignment of the compression connector 106 to the PCB 104.

To provide a relatively even compression force to press the PCB 104 against the compression connector 106, the example deflection spring 202 exhibits a relatively raised and/or curved overall shape such that the medial portion 204 is raised (in the view of FIG. 3) in relation to the intermediate portions 206 and the end portions 208. In other words, according to examples disclosed herein, the medial portion 204 is ramped and/or elevated from the end portions 208 with the intermediate portions 206 acting as a transition between the medial portion 204 and the end portions 208. Accordingly, coupling and/or fastening the fastener 210 corresponding to the medial portion 204 to the respective standoff 302 of the backplate 108 while the fasteners 210 at the end portions 208 at least partially constrain (e.g., laterally constrain) the deflection spring 202 at the end portions 208, causes the medial portion 204 to deflect and/or bend toward the PCB 104. In turn, the example curved portions 205 that exhibit a generally convex shape toward the PCB 104 are pushed and/or displaced to distribute a force onto at least one surface of the PCB 104 in a relatively even manner. Particularly, pins and/or a connector of the PCB 104 are compressed against receptacles of the compression connector 106 in a relatively even manner due to the curved portions 205 pressing against the surface(s) of the PCB 104. According to examples disclosed herein, a presence of the apertures 207 can facilitate flexure and/or bending of the curved portions 205 by reducing a cross-sectional profile area of the intermediate portions 206.

In this example, the medial portion 204 is substantially flat. However, in other examples, the medial portion 204 may be curved and/or exhibit multiple raised areas or portions (e.g., raised bump portions). For example, the medial portion 204 can include a generally curved portion and/or shape with respect to the PCB 104 such that the curved portion and/or the shapes can be pressed against the PCB 104 when the fasteners 210 are engaged with and/or threaded into the standoffs 302. Further, while three of the fasteners 210 are shown in this example, any other appropriate number of the fasteners 210 can be implemented instead (e.g., two, four, five, six, seven, eight, nine, ten, twenty, etc.). In some examples, the compression connector 106 is integral with, part of and/or extends from a printed circuit board (e.g., a motherboard, a module board, etc.).

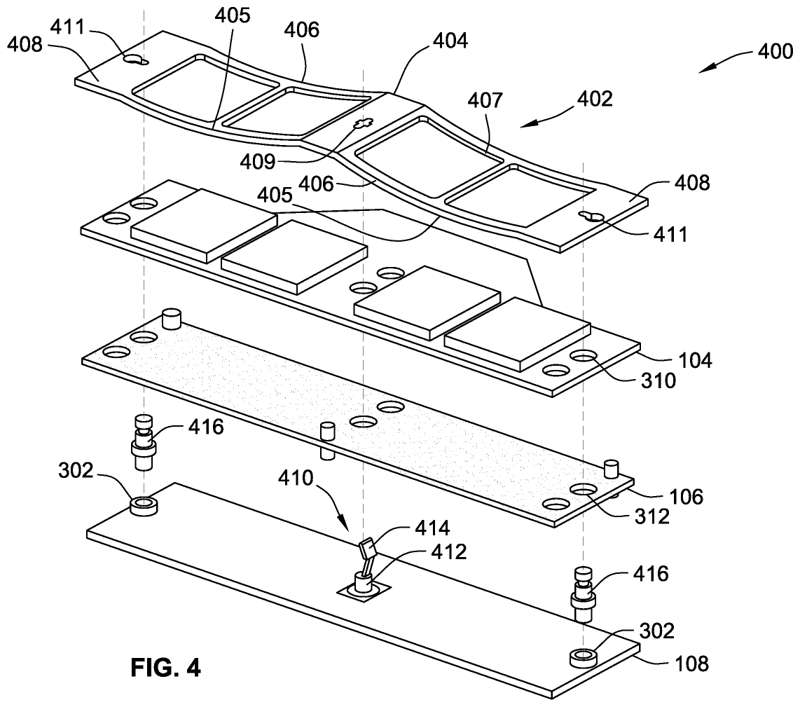

FIG. 4 is an exploded view of an example memory module assembly 400 having an alternative example deflection spring 402 in accordance with teachings of this disclosure. The deflection spring 402 of the illustrated example is similar to the deflection spring 202 shown in FIGS. 2 and 3 but, instead, utilizes a screwless design that can be assembled by hand (without tools) in a relatively quick manner. The example deflection spring 402 includes a medial portion (e.g., means for deflecting) 404, intermediate portions 406 defining curved portions 405 apertures 407, and end portions 408. The example medial portion 404 includes a slotted aperture 409 while the example end portions 408 include respective apertures (e.g., keyhole shaped apertures) 411. In this example, standoffs (e.g., shoulder standoffs) 416 are mounted to the backplate 108 and extend through the apertures 312 of the compression connector 106 and the apertures 310 of the PCB 104 when the memory module assembly 400 is assembled.

In the illustrated example of FIG. 4, the backplate 108 includes a lever spring (e.g., a lock, a releasable lock, a lever spring lock, means for locking) 410 coupled thereto. In turn, the example lever spring 410 includes a base 412 and an arm 414 attached to and extends from the base 412. In this example, the arm 414 is at least partially composed of a metal (e.g., a sheet metal, steel aluminum, stainless steel, titanium, copper, etc.) or a plastic. However, any other appropriate material can be implemented instead.

To press the PCB 104 against the compression connector 106, the example standoffs 416, which extend through the apertures 310 and the apertures 312, are placed into the apertures 411 of the deflection spring 402 while a distal end or portion of the arm 414 of the lever spring 410 is inserted into the aperture 409 of the deflection spring 402. In the illustrated example of FIG. 4, an engagement of the distal end or portion of the arm 414 of the lever spring 410 with the aperture 409 causes the medial portion 404 to displace downward (in the view of FIG. 4). Accordingly, the aforementioned curved portion 405 pushes against the PCB 104, thereby causing the PCB 104 to be compressed against the compression connector 106 in a relatively even manner. In this example, an overall deflection of the deflection spring 402 caused by pushing down on the medial portion 404 results in the standoffs 416 engaging a narrower portion of the apertures 411 to restrain the end portions 408. As a result, the example memory module assembly 400 is assembled without necessitating tools while enabling relatively even compression of the PCB 104 against the compression connector 106.

In some examples, the standoffs 416 are threaded into standoffs, such as the standoffs 302. Additionally or alternatively, the lever spring 410 is threaded into the standoffs 302. While the single lever spring 410 is depicted in this example, in other examples, multiple ones of the lever springs 410 can be implemented.

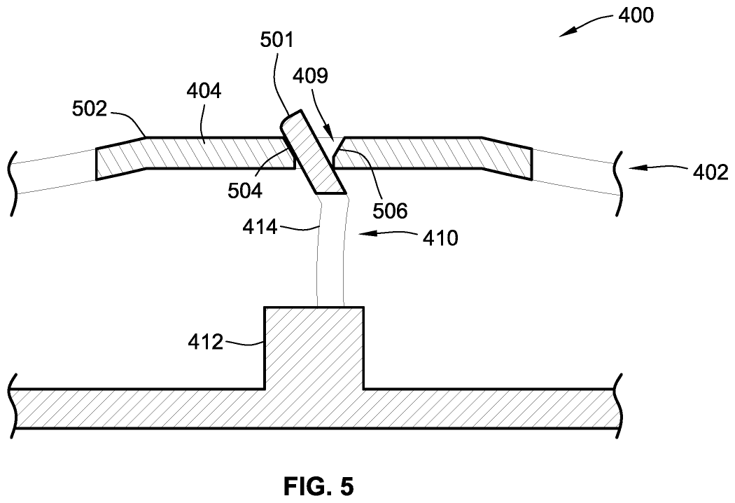

FIG. 5 is a detailed cross-sectional view of a portion of the example memory module 400 of FIG. 4 including the deflection spring 402 and the lever spring 410 (with the PCB 104 and the compression connector 106 removed for clarity). In this example, the aforementioned base 412 and the arm 414 of the lever spring 410 are depicted. According to examples disclosed herein, an angled portion 501 of the arm 414 at least partially extends past an outer surface 502 of the medial portion 404 of the deflection spring 402. In this example, the aperture 409 includes a taper (e.g., a tapered edge, a tapered surface, a tapered contour, etc.) 506 to facilitate contact between a surface 504 of the angled portion 501 and the taper 506 of the medial portion 404. When the medial portion 404 is deflected downward (in the view of FIG. 5), the interaction between the surface 504 and the taper 506 results in the medial portion 404 being retained by the arm 414, as well as the medial portion 404 being held downward (in the view of FIG. 5). The example lever spring geometry and part/component interactions depicted in FIGS. 2-5 (and other aspects disclosed herein) are only examples and any other appropriate shape, geometry, interface systems and/or component interaction can be implemented instead.

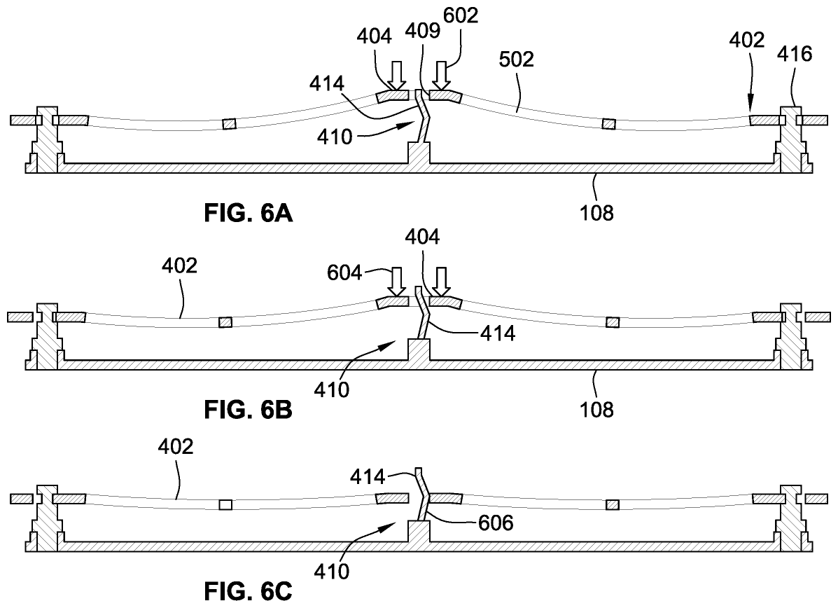

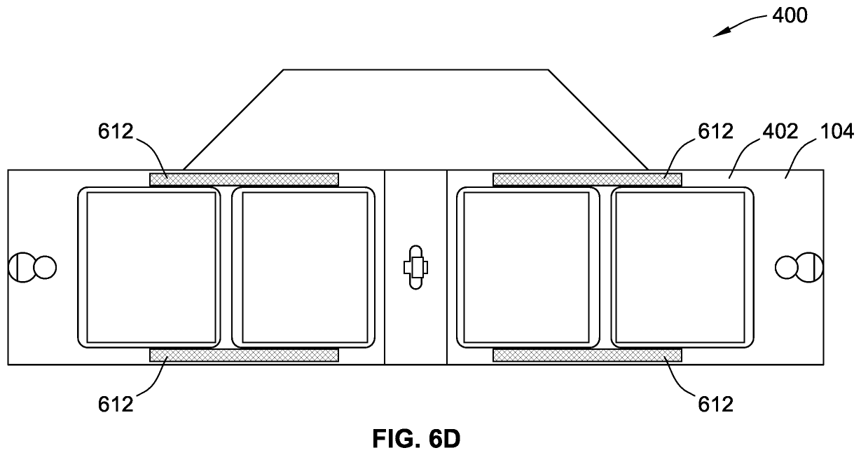

FIGS. 6A-6D illustrate example aspects of assembling the example deflection spring 402 shown in FIGS. 4 and 5. Turning to FIG. 6A, a cross-sectional view is depicted with the deflection spring 402 placed on the backplate 108 via the standoffs 416 (with the PCB 104 and the compression connector removed for clarity). In particular, the arm 414 of the lever spring 410 at least partially extends through the aperture 409 but does not extend past or does not extend significantly past the medial portion 404 of the deflection spring 402. Accordingly, a force is applied to the medial portion 404, as generally indicated by arrows 602.

FIG. 6B is a cross-sectional view depicting the medial portion 404 being pushed down toward the backplate 108 (e.g., by an operator or a technician). In the illustrated view of FIG. 6B, the arm 414 of the lever spring 410 is pushed along a direction generally indicated by arrows 604 and, as a result, the arm 414 extends past the medial portion 404 of the deflection spring 402, in contrast to the view depicted with respect to FIG. 6A.

Turning to FIG. 6C, the example arm 414 is shown in a locked position with respect to the deflection spring 402. In this example, the deflection spring 402 has been pushed downward (in the view of FIG. 6C), thereby causing the lever spring 410 to retain the deflection spring 402 in a vertical direction (in the view of FIG. 6C) while bending (e.g., elastically bending, elastically deforming) the deflection spring 402. According to examples disclosed herein, an inflection 606 (e.g., a kink, intermediate bend, etc.) in the arm 414 can be implemented to constrain/lock the medial portion 404, as well as prevent the medial portion 404 from extending further downward (in the view of FIG. 6C).

FIG. 6D is a top view depicting pressure/force areas on the example memory module assembly 400. As can be seen in the illustrated example of FIG. 6D, example regions 612 are areas of the PCB 104 that are compressed based on installation and/or coupling of the deflection spring 402. In particular, the example regions 612 correspond to areas that the deflection spring 402 presses/pushes down on the PCB 104 against the compression connector 106 (not shown in this view) with a relatively even distribution of force.

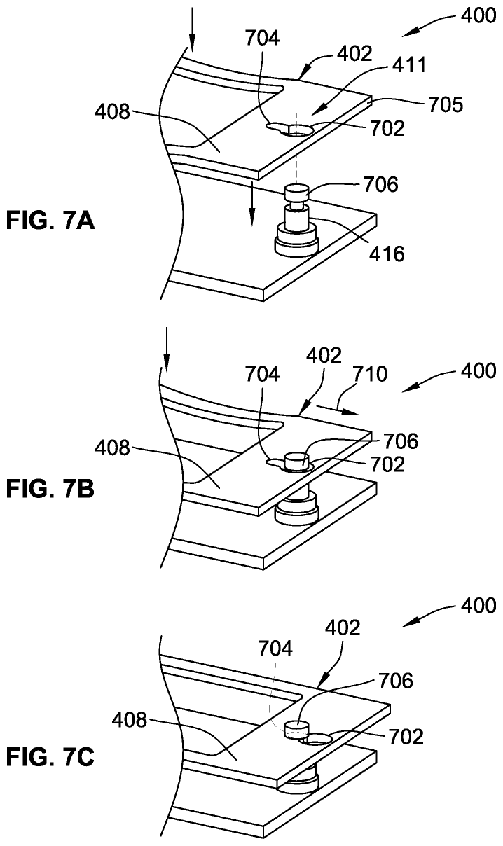

FIGS. 7A-7C illustrate example aspects of disassembling the example deflection spring 402 of the memory module assembly 400 shown connection with FIGS. 4-6D. Turning to FIG. 7A, the end portion 408 of the example deflection spring 402 includes the aforementioned aperture 411, which is generally keyhole shaped, for example. In particular, the example aperture 411 has a first opening 702 that is relatively larger than a second opening 704 that is further away from a distal end 705 of the deflection spring 402 than the opening 702. In other words, the opening 704 is inset from the opening 702. Further, the example standoff 416 is shown with a shoulder 706 that is initially aligned with the first opening 702.

FIG. 7B depicts the shoulder 706 inserted into the first opening 702 and displaced from the second opening 704. In this example, an arrow 710 generally indicates a direction of resultant displacement and/or movement of the end portion 408 when the deflection spring 402 is at least partially assembled onto (e.g., fully pressed onto) the memory module assembly 400 as a result of pressing/pushing down on the deflection spring 402.

FIG. 7C depicts a fully assembled configuration of the example deflection spring 402 with respect to the memory module assembly 400. In this example, the compression and/or bending of the deflection spring 402 causes the shoulder 706 to be placed in (e.g., inserted into, moved toward, etc.) the opening 704 instead of the opening 702. As a result of placing the shoulder 706 into the smaller opening 704, the shoulder 706 restrains the PCB 104 due to a relatively wider portion of the shoulder 706 being positioned over and/or adjacent the opening 704. As a result, the PCB 104 is restricted from vertical movement as well as movement in certain lateral directions (in the view of FIG. 7C).

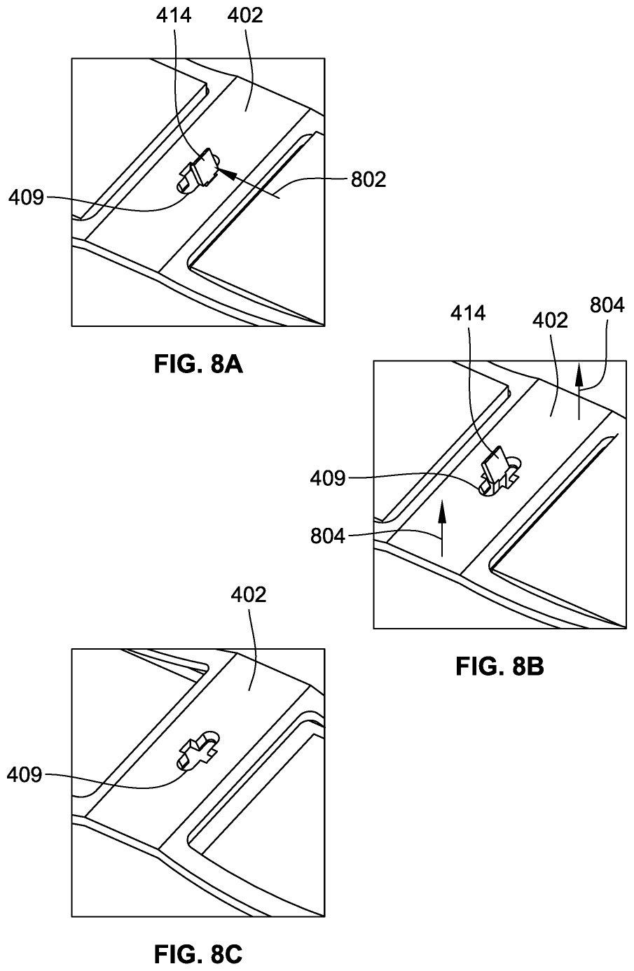

FIGS. 8A-8C illustrate example steps of disassembling the example deflection spring 402 shown in FIGS. 4-7C. FIG. 8A depicts a portion of the arm 414 extending through the aperture 409. In the illustrated view of FIG. 8A, the deflection spring 402 is still assembled. To release the deflection spring 402 from the arm 414, a force is applied along a direction generally indicated by an arrow 802.

FIG. 8B depicts the arm 414 being moved relative to the aperture 409 (in comparison to the view of FIG. 8A) to enable the deflection spring 402 to move away from the PCB 104 (not shown in this view). In this example, the deflection spring 402 is moved along a direction generally indicated by arrows 804.

FIG. 8C depicts the deflection spring 402 fully separated from the memory module assembly 400 and/or the PCB 104. Accordingly, in the illustrated view of FIG. 8C, the arm 414 no longer extends through the aperture 409.

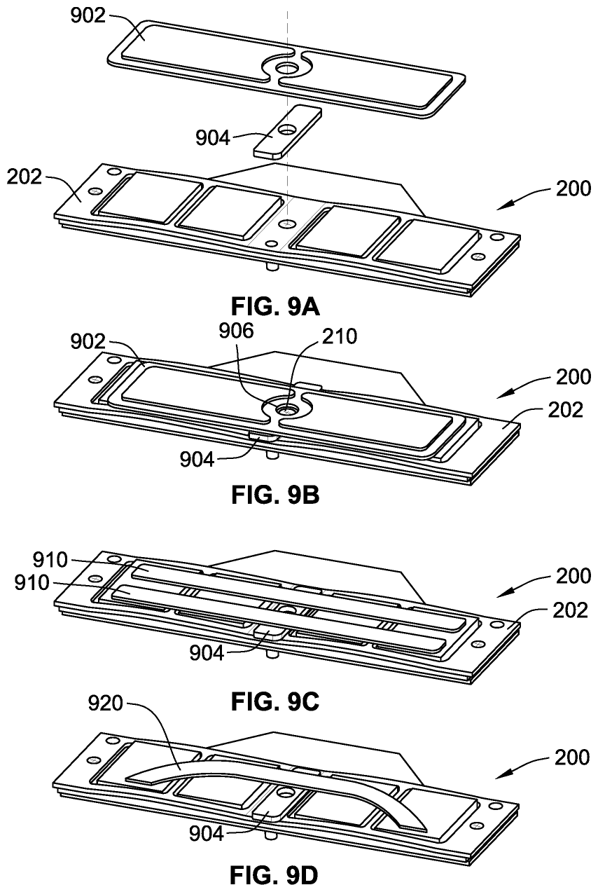

FIGS. 9A-9D illustrate example cooling implementations that can be implemented in and/or in conjunction with examples disclosed herein. Turning to FIG. 9A, an example vapor chamber 902 is shown in combination with the memory module assembly 200 shown in FIGS. 2 and 3. In this example, the vapor chamber 902 is placed onto the deflection spring 202. In some examples, a spacer 904 is positioned between the deflection spring 202 and the vapor chamber 902.

FIG. 9B depicts the aforementioned example vapor chamber 902 coupled to the memory module assembly 200 with the spacer 904 positioned therebetween. According to examples disclosed herein, the spacer 904 can accommodate deformation and/or bending of the deflection spring 202 and/or facilitate heat conduction from components mounted to the PCB 104. In some examples, the vapor chamber 902 includes an aperture 906 to accommodate the fastener 210.

In the illustrated example of FIG. 9C, heat pipes 910 are placed onto and/or span across the deflection spring 202 of the memory module assembly 200. While two of the heat pipes 910 are shown in the example of FIG. 9C, any appropriate other number (e.g., one, three, four, five, ten, twenty, etc.) of the heat pipes 910 can be implemented instead. In some examples, the spacer 904 is utilized.

FIG. 9D depicts the memory module assembly 200 with an example curved heat pipe 920 spanning across at least a portion of a width of the memory module assembly 200. According to examples disclosed herein, the spacer 904 can be implemented to at least partially support and/or align the curved heat pipe 920. In other examples, multiples ones of the heat pipe 920 are implemented.

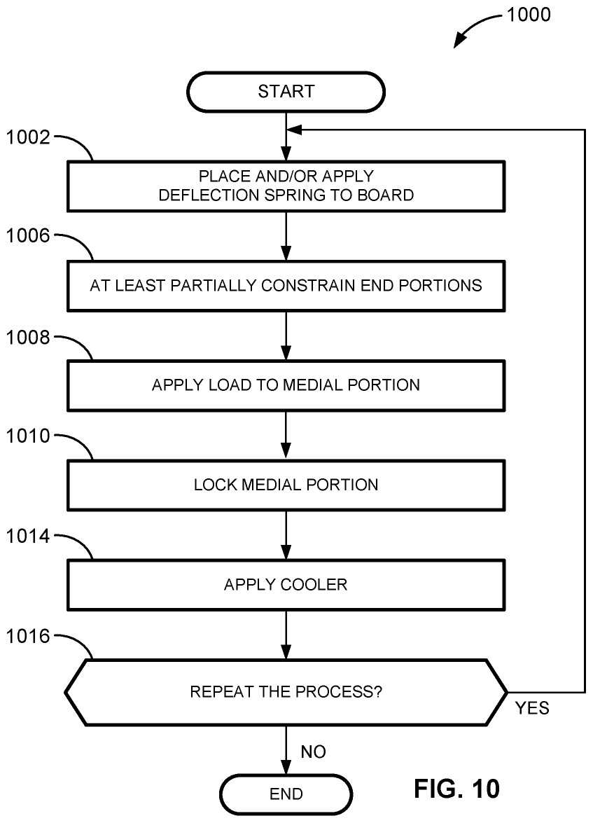

FIG. 10 is a flowchart representative of an example method 1000 to produce and/or assemble examples disclosed herein. In the illustrated example of FIG. 10, a memory module assembly is being manufactured and/or assembled. In particular, a memory module PCB (e.g., the PCB 104) is being coupled to a compression connector (e.g., the compression connector 106) that is mounted to a motherboard (e.g., a PC motherboard, a mobile device motherboard, etc.).

At block 1002, a deflection spring (e.g., the deflection spring 202, the deflection spring 402) is placed and/or applied to an electronics package (e.g., the electronics package 101), which includes the aforementioned PCB (e.g., the PCB 104) in this example.

At block 1006, end portions (e.g., distal end portions) of the deflection spring are at least partially constrained (e.g., fully constrained) by a support frame and/or chassis (e.g., the backplate 108). In some examples, fasteners and/or alignment components interface with the end portions of the deflection spring to constrain the end portions. In particular, the fasteners and/or the alignment components can rigidly constrain and/or limit movement of the end portions.

At block 1008, a load and/or pressure is applied to the medial portion positioned between the aforementioned end portions. In this example, the medial portion is raised and/or elevated relative to the end portions (e.g., the medial portion is further away from the PCB than the end portions). In the illustrated example of FIG. 10, the medial portion is pushed and/or displaced toward the PCB. In this example, as a result of applying the load and/or the pressure to the medial portion, at least a portion of the deflection spring presses down on the circuit board and, in turn, a connector of the circuit board is pressed into a compression connector (e.g., on another circuit board).

At block 1010, the medial/center portion is locked. For example, at least one fastener is received by a locking interface of the medial portion. In turn, the at least one fastener is coupled to (e.g., threaded into) the aforementioned support frame and/or the chassis to displace the locking interface and the medial portion, and cause at least a portion (e.g., curved portion) of the deflection spring to move toward the PCB to contact and press down on the PCB. Additionally or alternatively, the medial portion is locked to a lever spring other retention device associated with the support frame and/or the chassis (e.g., without the use of fasteners and associated hardware).

At block 1014, in some examples, a cooler and/or cooling device is applied to the deflection spring and/or the circuit board. The cooler and/or cooling device can include, but is not limited to, a vapor chamber, a heat pipe, a thermoelectric cooler, a heatsink array, etc. In some examples, a spacer is positioned between the cooler and the cantilever spring.

At block 1016, it is determined whether to repeat the process. If the process is to be repeated (block 1016), control of the process returns to block 1002. Otherwise, the process ends. This determination may be based on whether additional deflection springs are to be assembled and/or whether additional assemblies and/or modules are to be produced.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

As used herein, the term “electronics package” refers to any semiconductor package, a device package, an electronic device package, an electronics package, a circuit board assembly, a circuit board module, etc. As used herein, the term “locking interface” refers to a physical feature that is used for at least partially constraining a component. Accordingly, the term “locking interface” can refer to an aperture, a detent, a mating feature, a fastener receptacle, a snap component, etc.

Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

Example methods, apparatus, systems, and articles of manufacture disclosed herein enable effective and relatively even compression forces that are applied to electronics packages. Further examples and combinations thereof include the following:

Example 1 includes a deflection spring for an electronics package, the deflection spring comprising first and second end portions having first and second locking interfaces, respectively, to at least partially constrain the first and second end portions relative to a support, a curved portion, and a medial portion having a third locking interface to fix the medial portion relative to the support, wherein fixing the medial portion to the support causes the curved portion to contact and press against the electronics package.

Example 2 includes the deflection spring as defined in example 1, wherein the third locking interface is engaged when the medial portion is pushed toward the support.

Example 3 includes the deflection spring as defined in example 2, wherein the third locking interface includes a slot-shaped aperture to restrain at least a portion of a lever spring.

Example 4 includes the deflection spring as defined in example 3, wherein the third locking interface includes a taper to guide the lever spring to retain the medial portion.

Example 5 includes the deflection spring as defined in example 1, wherein the first and second locking interfaces respectively include an aperture to receive a fastener, the fastener coupled to a respective spacer extending from the at least one support.

Example 6 includes the deflection spring as defined in example 5, wherein the aperture is shaped as overlapping circles of different sizes to define an hourglass shape of the aperture.

Example 7 includes the deflection spring as defined in example 1, wherein the curved portion has a convex shape.

Example 8 includes the deflection spring as defined in example 1, wherein the medial portion includes a flat surface, and the curved portion includes (i) a first convex portion extending between the flat surface and the first end portion, and (ii) a second convex portion extending between the flat surface and the second end portion.

Example 9 includes the deflection spring as defined in example 1, wherein the curved portion includes an aperture to enable an electronic component of the electronic package to at least partially extend therethrough.

Example 10 includes an electronics assembly comprising an electronics package, a support frame to support the electronics package at a first side of the electronics package, a lock, and a deflection spring at a second side of the electronics package opposite the first side, the deflection spring at least partially constrained to the support frame, the deflection spring including a medial portion between distal ends of the deflection spring, the medial portion raised relative to the distal ends, the medial portion to be coupled to the lock by pushing or bending the medial portion to engage the lock, and curved portions extending between the medial portion and the distal ends, the curved portions to press against a surface of the electronics package.

Example 11 includes the electronics assembly as defined in example 10, wherein the support frame includes a backplate to support a first connector of a motherboard, the first connector to receive a second connector of the electronics package, the first and second connectors defining a compression connector interface.

Example 12 includes the electronics assembly as defined in example 11, further including a standoff extending between the electronics package and the motherboard.

Example 13 includes the electronics assembly as defined in example 12, wherein the standoff includes an aperture to receive a fastener to secure at least one of the distal ends to the standoff.

Example 14 includes the electronics assembly as defined in example 10, wherein the lock includes a lever spring extending from the support frame, at least a portion of the lever spring to be received and retained by an aperture of the medial portion when the medial portion is pushed toward the electronics package.

Example 15 includes the electronics assembly as defined in example 10, wherein at least one of the curved portions of the spring includes at least one opening corresponding to an exposed portion of an electronic component supported by the electronics package.

Example 16 includes the electronics assembly as defined in example 15, further including at least one of a heat pipe or a vapor chamber coupled to the exposed portion.

Example 17 includes the electronics assembly as defined in example 10, wherein the medial portion is flat.

Example 18 includes the electronics assembly as defined in example 10, wherein the electronics package includes a memory module.

Example 19 includes a method comprising placing a deflection spring onto an electronics package supported by a frame, at least partially constraining end portions of the deflection spring relative to the frame, and pushing a medial portion of the deflection spring to engage a lock and to cause curved portions of the deflection spring to compress against at least one of the electronics package or an electronic component mounted thereon.

Example 20 includes the method as defined in example 19, wherein the at least partially constraining the end portions includes inserting shoulders that extend from the frame into hour-glass shaped apertures of the end portions, and causing the end portions to displace from the medial portion when the medial portion is pushed.

Example 21 includes an apparatus comprising means for restraining, means for contacting an electronics package, and means for deflecting.

Example 22 includes the apparatus as defined in example 19, further including means for locking the means for deflecting.

From the foregoing, it will be appreciated that example systems, apparatus, articles of manufacture, and methods have been disclosed that enable consistent and evenly distributed compression loading of connection interfaces with respect to, for example, electronics packages and/or electronics devices. Examples disclosed herein can improve signal integrity and/or quality by ensuring consistent coupling interfaces that are resistant to the effects of temperature cycling, movement and/or impact/shock.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A deflection spring for an electronics package, the deflection spring comprising:
first and second end portions having first and second locking interfaces, respectively, to at least partially constrain the first and second end portions relative to a support;
a curved portion; and
a medial portion having a third locking interface to fix the medial portion relative to the support, wherein fixing the medial portion relative to the support causes the curved portion to contact and press against the electronics package.

2. The deflection spring as defined in claim 1, wherein the third locking interface is engaged when the medial portion is pushed toward the support.

3. The deflection spring as defined in claim 2, wherein the third locking interface includes a slot-shaped aperture to restrain at least a portion of a lever spring.

4. The deflection spring as defined in claim 3, wherein the third locking interface includes a taper to guide the lever spring to retain the medial portion.

5. The deflection spring as defined in claim 1, wherein the first and second locking interfaces respectively include an aperture to receive a fastener, the fastener coupled to a respective spacer extending from the support.

6. The deflection spring as defined in claim 5, wherein the aperture is shaped as overlapping circles of different sizes to define an hourglass shape of the aperture.

7. The deflection spring as defined in claim 1, wherein the curved portion has a convex shape.

8. The deflection spring as defined in claim 1, wherein the medial portion includes a flat surface, and the curved portion includes: (i) a first convex portion extending between the flat surface and the first end portion, and (ii) a second convex portion extending between the flat surface and the second end portion.

9. The deflection spring as defined in claim 1, wherein the curved portion includes an aperture to enable an electronic component of the electronic package to at least partially extend therethrough.

10. An electronics assembly comprising:
an electronics package;
a support frame to support the electronics package at a first side of the electronics package;
a lock; and
a deflection spring at a second side of the electronics package opposite the first side, the deflection spring at least partially constrained to the support frame, the deflection spring including:
a medial portion between distal ends of the deflection spring, the medial portion raised relative to the distal ends, the medial portion to be coupled to the lock by pushing or bending the medial portion to engage the lock; and
curved portions extending between the medial portion and the distal ends, the curved portions to press against a surface of the electronics package.

11. The electronics assembly as defined in claim 10, wherein the support frame includes a backplate to support a first connector of a motherboard, the first connector to receive a second connector of the electronics package, the first and second connectors defining a compression connector interface.

12. The electronics assembly as defined in claim 11, further including a standoff extending between the electronics package and the motherboard.

13. The electronics assembly as defined in claim 12, wherein the standoff includes an aperture to receive a fastener to secure at least one of the distal ends to the standoff.

14. The electronics assembly as defined in claim 10, wherein the lock includes a lever spring extending from the support frame, at least a portion of the lever spring to be received and retained by an aperture of the medial portion when the medial portion is pushed toward the electronics package.

15. The electronics assembly as defined in claim 10, wherein at least one of the curved portions of the spring includes at least one opening corresponding to an exposed portion of an electronic component supported by the electronics package.

16. The electronics assembly as defined in claim 15, further including at least one of a heat pipe or a vapor chamber coupled to the exposed portion.

17. The electronics assembly as defined in claim 10, wherein the medial portion is flat.

18. The electronics assembly as defined in claim 10, wherein the electronics package includes a memory module.

19. An apparatus comprising:
means for restraining;
means for contacting an electronics package; and
means for deflecting.

20. The apparatus as defined in claim 19, further including means for locking the means for deflecting.
